(19) United States
(12) Patent Application Publication
(10) Pub. No.: US 2009/0183681 A1
(43) Pub. Date: Jul. 23, 2009

(54) Slotted Electrode and Plasma Apparatus Using the Same

(75) Inventors: Ming-Hung Huang, Lujhu Township (TW); Kung-Hsu Yeh, Tainan City (TW); Cheng-An Yang, Sinying City (TW); Chien-Li Ho, Sinhua Township (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: CONTREL TECHNOLOGY CO., LTD., Tainan County (TW)

(21) Appl. No.: 12/057,008

(22) Filed: Mar. 27, 2008

(30) Foreign Application Priority Data
Jan. 18, 2008 (TW) 97201212

(51) Int. Cl. C23C 16/00

(52) U.S. Cl. 118/723 I

(57) ABSTRACT

A slotted electrode with uniform distribution of electric field and a process apparatus using the slotted electrode are disclosed. The slotted electrode comprises an electrode plate; a perturbation slot segment; a first edge perturbation slot segment; two second edge perturbation slot segments. By using the slot segments of the electrode plate, the electrode plate can improve the uniformity of plasma density, and is suitable for use in various types of substrate and can be widely applied in a plasma process system.

### RELATED APPLICATIONS

This application claims priority to Taiwan Application Serial Number 97201212, filed Jan. 18, 2008, which is herein incorporated by reference.

### BACKGROUND

1. Field of Invention

The present invention relates to an electrode, and more particularly, to a slotted electrode with adjustable electric filed distribution for use in a plasma process apparatus.

2. Description of Related Art

In the current semiconductor process technologies, plasma can be used for performing effective film processing and etching tasks such as plasma-assisted chemical vapor deposition, plasma-assisted etching and plasma polymerization, and those processing techniques are applied in various industries such as TFT (Thin Film Transistor) LCD (Liquid Crystal Display) factories, solar energy manufacturers and foundries. For example, In the process for fabricating a microcrystalline silicon thin-film solar cell, a plasma-enhanced chemical vapor deposition (PECVD) process is generally first performed to introduce a great of hydrogen to dilute silane, and then microcrystalline silicon thin films are formed by reaction, thereby promoting various electrical features thereof so as to achieve highly efficient yield. With the raising the plasma frequencies in these processes, theirs film-coating rate is also increased. However, when the area of a substrate desired to be film-coated increases, the electromagnetic wave propagated thereon will cause the variation of electric field due its phase change, thus relatively affecting the plasma uniformity and film-coating rate. Especially when the size of the current film-coated substrate has increased from an eight or twelve-inch wafer to a large-area glass substrate (greater than 1 m²) developed in the current TFT factory or solar energy manufacturer, the aforementioned problem will seriously affect the efficiency and cost of mass production.

Hence, in order to resolve the aforementioned problem, there is a need to provide an electrode having the capability of generating uniform plasma density for overcoming the shortcomings of the convention skill.

### SUMMARY

Hence, an aspect of the present invention is directed to a slotted electrode having uniform electric field distribution, and the slotted electrode has an adjustable electric field for use in film deposition and etching processes conducted in plasma apparatuses.

An embodiment of a slotted electrode comprises an electrode plate, a perturbation slot segment, a first edge perturbation slot segment and at least one second edge perturbation slot segment, wherein the electrode plate is used for generating an electric field; the perturbation slot segment is used for controlling the intensity distribution of the electric field; the first edge perturbation slot segment is sued for controlling the intensity distribution of the electric field on one edge of the electrode plate; and the second edge perturbation slot segment is orthogonal to the first edge perturbation slot segment, wherein the at least one second edge perturbation slot segment is adjacent to at least one side of the electrode plate, thereby controlling the intensity distribution of the electric field on another at least one edge of the electrode plate.

In another embodiment, the electrode plate is applicable to an atmospheric pressure chemical vapor deposition (APCVD) system, a low pressure chemical vapor deposition (LPCVD) system, a high density plasma chemical vapor deposition (HDPCVD) system, a PECVD system and an inductively coupled plasma (ICP) etching system.

In another embodiment, the shape of the electrode plate from the top view is selected from the group consisting of a rectangle, a circle, a hexagon and a polygon.

In another embodiment, a radio frequency (RF) current source electrically connected to the electrode plate is operated at a frequency ranged from 10 MHz to 10 GHz, and preferably at 13.56 MHz.

In another embodiment, the length and width of the electrode plate are ranged from 0.0001 to 0.5 of the guided wavelength relative to the operation frequency of the RF current source.

In another embodiment, the impedance of the RF current source fed to the electrode plate is ranged from 1 ohm to 300 ohm.

An embodiment of a capacitor-coupled plasma apparatus comprises a chamber, a stage disposed on a chamber surface of the chamber, the aforementioned slotted electrode disposed on the stage, a gas outlet and a gas inlet, wherein the chamber is grounded, and is used for providing required processing space; the slotted electrode is used for generating an electric field; the gas outlet is disposed on a chamber surface of the chamber for exhausting gas out of the chamber; and the gas inlet is disposed on a chamber surface of the chamber for introducing gas into the chamber.

In another embodiment, a processed substrate is disposed above the slotted electrode.

In another embodiment, the processed substrate does not contact the perturbation slot segment, the first edge perturbation slot segment and the second edge perturbation slot segment.

In another embodiment, the capacitor-coupled plasma apparatus is an injection-typed capacitor-coupled plasma apparatus, wherein the gas inlet located at the surface of the chamber opposite to the slotted electrode.

In another embodiment, the impedance of a RF current source electrically connected to the slotted electrode is adjusted by using an impedance matching circuit.

In another embodiment, the chamber is a grounded metal chamber.

It is to be understood that both the foregoing general description and the following detailed description are examples, and are intended to provide further explanation of the present invention as claimed.

### BRIEF DESCRIPTION OF THE DRAWINGS

The present invention will become more fully understood from the detailed description given herein below and the accompanying drawings, given by way of illustration only and thus not intended to be limitative of the present invention, where:

FIG. 1 is a schematic diagram illustrating the structure of a slotted electrode having uniform electric field distribution according to an embodiment of the present invention;

FIG. 2 is a diagram showing the electric field distribution for the slotted electrode of the embodiment of the present invention having a perturbation slot segment;

FIG. 3 is a diagram showing the electric field distribution for the slotted electrode of the embodiment of the present invention having the perturbation slot segment and a first edge perturbation slot segment;

FIG. 4 is a diagram showing the electric field distribution for the slotted electrode of the embodiment of the present invention having the perturbation slot segment, the first edge perturbation slot segment and two second edge perturbation slot segments;

FIG. 5 is a schematic diagram illustrating a capacitor-coupled plasma apparatus according to another embodiment of the present invention; and

FIG. 6 is a schematic diagram illustrating an injection-typed capacitor-coupled plasma apparatus according to another embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

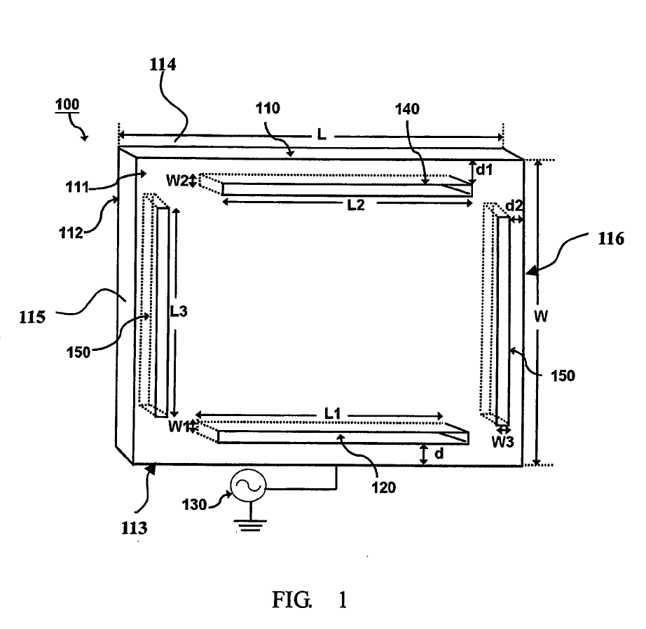

Referring FIG. 1, FIG. 1 is a schematic diagram illustrating the structure of a slotted electrode 100 having uniform electric field distribution according to an embodiment of the present invention. According to the present embodiment, the slotted electrode 100 comprises an electrode plate 110, a perturbation slot segment 120, a first edge perturbation slot segment 140 and at least one second edge perturbation slot segment 150 (such as two second edge perturbation slot segments 150). The electrode plate 110 has a first surface 111, a second surface 112 opposite to the first surface 111, a first side 113, a second side 114 opposite to the first side 113, a third side 115 and a fourth side 116 opposite to the third side 115, and the electrode plate 110 is electrically connected to a RF current source 130 for generating an electric field. The perturbation slot segment 120 is adjacent to the first side 113 of the electrode. An etching process can be used to form the perturbation slot segment 120 symmetrically from the first surface 111 to the second surface 112 of the electrode plate 110, wherein the perturbation slot segment 120 is used for controlling the intensity distribution of the electric field. The first edge perturbation slot segment 140 is located opposite to the perturbation slot segment 120, and is adjacent to the second side 114 of the electrode plate 110. An etching process can be used to form the first edge perturbation slot segment 140 symmetrically from the first surface 111 to the second surface 112 of the electrode plate 110, wherein the first edge perturbation slot segment 140 is used for controlling the intensity distribution of the electric field on one edge (near the second side 114) of the electrode plate 110. The second edge perturbation slot segments 150 are oriented orthogonal to the first edge perturbation slot segment, respectively. The second edge perturbation slot segments 150 are respectively adjacent to the third side 115 and the fourth side 116 of the electrode plate 110, and are symmetrically formed from the first surface 111 to the second surface 112 of the electrode plate 110, wherein the second edge perturbation slot segments 150 are used for controlling the intensity distribution of the electric field on another two edges (near the third side 115 and the fourth side 116) of the electrode plate 11.

With respect to a vapor deposition system required for a plasma reaction process, the electrode plate 110 can be applied to an APCVD system, a LPCVD system, a HDPCVD system, a PECVD system and an ICP etching system, wherein the material forming the electrode plate 110 can be selected from the group consisting of aluminum, aluminum-coated material, silicon, quartz, silicon carbide, silicon nitride, carbon, aluminum nitride, sapphire, polyidmide and teflon. Since the processed substrates treated in the current solar cell industries, optoelectronic display industries and integrated circuit (IC) industries are different in size, the shape of the electrode plate 110 from the top view can a rectangle, a circle, a hexagon or a polygon, so that the electrode plate 110 can be provided for the processed substrates of various shapes. The embodiment of the present invention adopts a rectangular electrode plate. For performing a process, a plasma frequency has be considered for selecting the size of the electrode plate 110, wherein the size of the electrode plate 110 can be defined by the guided wavelength relative to the plasma frequency operated thereby. The RF current source 130 electrically connected to the electrode plate 110 is operated at a frequency ranged from about 10 MHz to about 10 GHz, wherein the optimum operation frequency in the present embodiment is about 13.56 MHz. The size (such as the length and width) of the electrode plate is ranged from about 0.0001 to about 0.5 of the guided wavelength relative to the operation frequency of the RF current source, wherein the length L of the electrode plate 110 is preferably about 0.08 of the guided wavelength, and the width W of the electrode plate 110 is preferably about 0.03 of the guided wavelength. Further, when a process is performed, the current-feeding situation from the RF current source 130 to the electrode plate 110 has to be considered. For preventing too much reflection of electromagnetic wave from occurring, the impedance of the RF current source 130 fed to the electrode plate 110 is ranged from about 1 ohm to about 300 ohm, and is preferably about 50 ohm. On the other hand, the impedance of the RF current source 130 can be adjusted by using an impedance matching circuit (not shown).

In order to achieve the efficacy of improving the plasma uniformity by using the slotted electrode 100 having uniform electric field distribution, the perturbation slot segment 120 is added to the electrode plate 110, and is located at the same side with the RF current source 130. The function of the perturbation slot segment 120 is to pertubate the current direction fed by the RF current source 130, thereby altering the electric field distribution on the slotted electrode 100, further affecting the plasma density on the slotted electrode 100. With regard to the design of the perturbation slot segment 120, the perturbation slot segment 120 does not contact a processed substrate treated by the apparatus using the slotted electrode 100, and the degree of perturbation will be changed simultaneously with the change of the size of the perturbation slot segment 120. Hence, the size of the perturbation slot segment 120 has to be determined under the presupposition of well controlling the electric field on the electrode plate 110, wherein the length L1 of the perturbation slot segment 120 has to be smaller than about 95% of the length L of the electrode plate 110, and the width W1 of the perturbation slot segment 120 has to be smaller than about 1% of the width W of the electrode plate 110. In the present embodiment, the length L1 of the perturbation slot segment 120 is preferably smaller than about 84% of the length L of the electrode plate 110, and the width W1 of the perturbation slot segment 120 is preferably smaller than about 0.8% of the width W of the electrode plate 110. Meanwhile, the distance d between the RF current source 130 and the perturbation slot segment 120 also affect the intensity of the current fed therebetween. When the distance d is too small, the perturbation effect by the perturbation slot segment 120 is relatively large; and when the distance d is too larger, the perturbation effect by the perturbation slot segment 120 is relatively small. In the present embodiment, the distance d between the RF current source 130 and the perturbation slot segment 120 is preferably about 0.024% of the width W of the electrode plate 110. Since the perturbation slot segment 120 is mainly to pertubate the current fed to the electrode plate 110, and thus the electric field generated by the current fed to and flowing on the electrode plate 110 will be changed due to the structure of the electrode plate 110. For example, conventionally, the electric field on the edge of the electrode plate 110 suffers a problem of ununiformity, and thus the first edge perturbation slot segment 140 is used to improve the problem of ununiform electric field on the edge of the electrode plate 110, wherein the first edge perturbation slot segment 140 does not contact the processed substrate. In the present embodiment, the length L2 of the first edge perturbation slot segment 140 is smaller than about 95% of the length L of the electrode plate 110, and the width W2 of the first edge perturbation slot segment 140 is smaller than about 1% of the width W of the electrode plate 110, wherein the length L2 of the first edge perturbation slot segment 140 is preferably smaller than about 84% of the length L of the electrode plate 110, and the width W2 of the first edge perturbation slot segment 140 is preferably smaller than about 0.8% of the width W of the electrode plate 110, and the distance d1 between the first edge perturbation slot segment 140 and the edge (the side 114) of the electrode plate 110 is preferably about 2% of the width W of the electrode plate 110. Since it is desirable to further improve the uniformity of electric field, at least one (such as two) second edge perturbation slot segments 150 are required to be disposed near two sides (the third side 115 and the fourth side 116), respectively. The second edge perturbation slot segments 150 are oriented orthogonal to the first edge perturbation slot segment 140 and the perturbation slot segment 120, respectively, and do not contact the processed substrate. The length L3 of each second edge perturbation slot segment 150 is smaller than about 60% of the width W of the electrode plate 110, and the width W3 of each second edge perturbation slot segment 150 is smaller than about 1% of the length L of the electrode plate 110, wherein the length L3 of each second edge perturbation slot segment 150 is preferably about 57% of the width W of the electrode plate 110, and the width W3 of each second edge perturbation slot segment 150 is preferably about 0.66% of the length L of the electrode plate 110, and the distance d2 between the second edge perturbation slot segment 150 and the edge (the third side 115 or the fourth side 116) of the electrode plate 110 is preferably about 1.3% of the length L of the electrode plate 110.

Further, since a plasma process has to be performed under a vacuum and non-polluted environment, the slotted electrode 100 having uniform electric field distribution is enclosed in a grounded metal chamber for performing the plasma process.

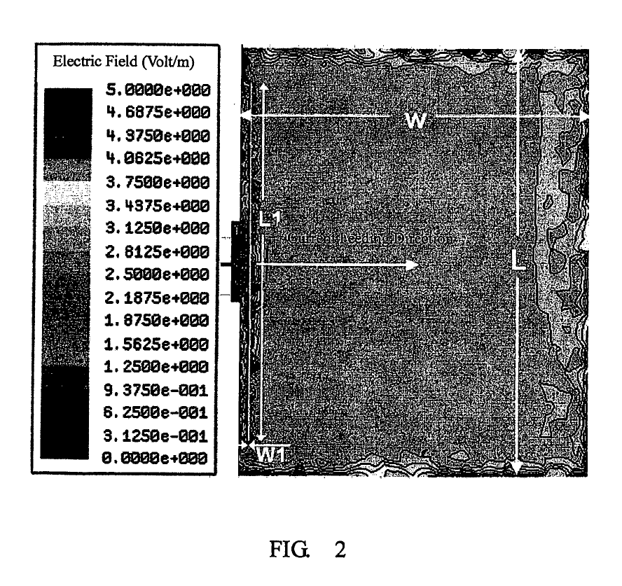

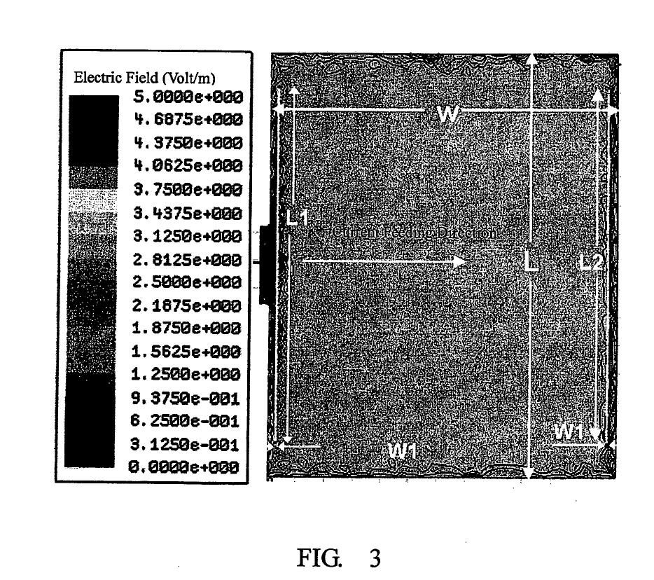

Referring to FIG. 2, FIG. 2 is an electric field analysis diagram for the electrode plate 110 with the addition of the perturbation slot segment 120 being operated at a frequency of 13.56 MHz, wherein, in the present embodiment, the length L of the electrode plate 110 is 1510 mm, and the width W thereof is 1230 mm, and the length L1 of the perturbation slot segment 120 is 1275 mm, and the width W1 thereof is 10 mm, and the distance d between the RD current source 130 and the perturbation slot segment 120 is 30 mm. Such as shown in FIG. 2, the uniformity of the electric field distribution on the electrode plate 110 is improved due to the addition of the perturbation slot segment 120. Referring to FIG. 3, FIG. 3 is an electric field analysis diagram for the electrode plate 110 with the addition of the perturbation slot segment 120 and the first edge perturbation slot segment 140 being operated at a frequency of 13.56 MHz, wherein the size parameters of the electrode plate 110 and the perturbation slot segment 120 are the same as those used in FIG. 2, and, in the present embodiment, the length L2 of the first edge perturbation slot segment 140 is 1275 mm, and the width W2 thereof is 10 mm, and the distance d1 between the first edge perturbation slot segment 140 and the edge of the electrode plate 110 is 25 mm. The electric field on the electrode plate 110 shown in FIG. 3 has smaller variance than that shown in FIG. 2, and thus the uniformity of the electric field distribution on the electrode plate 110 is further improved due to the addition of the first edge perturbation slot segment 140. Besides, the electric field distribution on the electrode plate 110 can be further improved with the addition of the second edge perturbation slot segments 150.

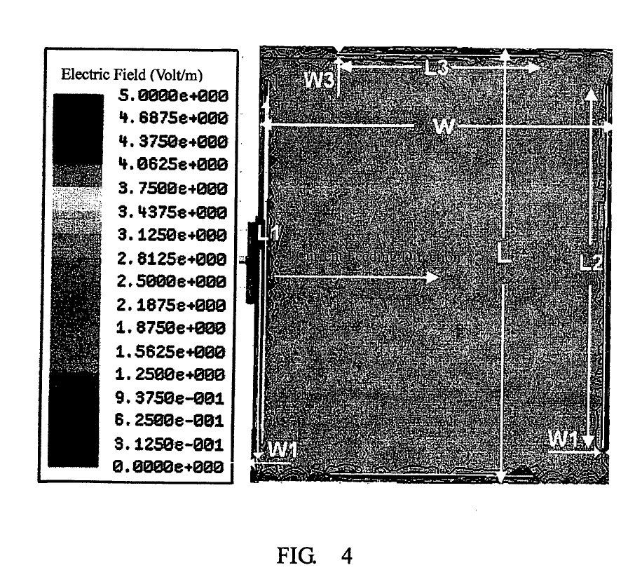

Referring to FIG. 4, FIG. 4 is an electric field analysis diagram for the electrode plate 110 with the addition of the perturbation slot segment 120, the first edge perturbation slot segment 140 and the second edge perturbation slot segments 150 being operated at a frequency of 13.56 MHz, wherein the size parameters of the electrode plate 110, the perturbation slot segment 120 and the first edge perturbation slot segment 140 are the same as those used in FIG. 3, and, in the present embodiment, the length L3 of each second edge perturbation slot segments 150 is 700 mm, and the width W2 thereof is 10 mm, and the distance d2 between the respective second edge perturbation slot segment 150 and the edge of the electrode plate 110 is 20 mm. The electric field on the electrode plate 110 shown in FIG. 4 has smaller variance than that shown in FIG. 3, and thus the uniformity of the electric field distribution on the electrode plate 110 is further improved due to the addition of the second edge perturbation slot segments 150. Besides, the electric field distribution on the electrode plate 110 can be further improved with the addition of the second edge perturbation slot segments 150.

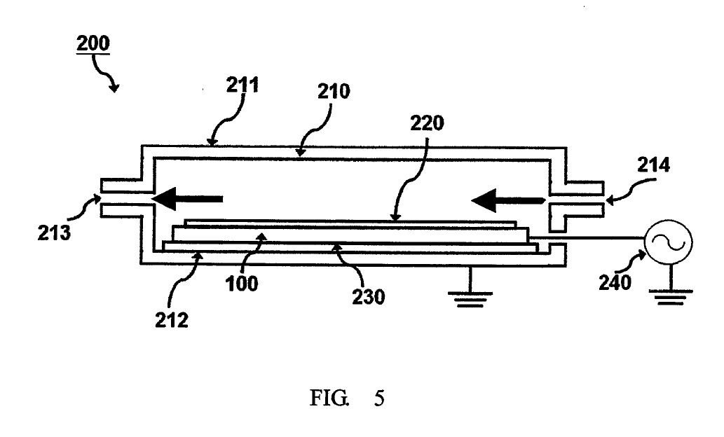

Referring to FIG. 5, FIG. 5 is a schematic diagram illustrating a capacitor-coupled plasma apparatus 200 according to another embodiment of the present invention. The capacitor-coupled plasma apparatus 200 comprises a chamber 210, a stage 230, a slotted electrode 100 having uniform electric field distribution, a gas outlet 213 and a gas inlet 214.

In the present embodiment, the chamber 210 has a first chamber surface 212 grounded and a second chamber surface 211, and is used for providing required processing space. The stage 230 is disposed on the first chamber surface 212 for holding the electrode required for performing a process in the chamber 210, wherein the stage 230 adopts isolation material to electrically isolate the first chamber surface 212 from the electrode required for performing the process, wherein the material forming the stage 230 can be selected from the group consisting of silicon, GaAs, ceramics, glass, fiberglass, hydrocarbon-ceramic composites, teflon, teflon-fiberglass composites and teflon-ceramic composites.

In the chamber 210, the slotted electrode 100 is disposed on the stage 230 for generating a uniform electric field in the chamber 210. A capacitor effect is formed between the slotted electrode 100 and the second chamber surface 211, thereby forming plasma, wherein the optimum length of the slotted electrode 100 is about 0.08 of the guided wavelength, and the optimum width of thereof is about 0.03 of the guided wavelength. When a process is performed, a processed substrate 220 is disposed above the slotted electrode 100 for performing plasma reaction, wherein the material forming the processed substrate 220 is selected from the group consisting of a suspension substrate, a silicon substrate, a GaAs substrate, a ceramic substrate, a glass substrate, a fiberglass substrate, a hydrocarbon-ceramic substrate, a teflon substrate, a teflon-fiberglass substrate and a teflon-ceramic substrate.

In the present embodiment, the gas outlet 213 is disposed on the second chamber surface 211 for exhausting the waste gas generated by the process in the chamber 210 and vacuuming the chamber 210. The gas inlet 214 is disposed on the second chamber surface 211 for introducing gas required for generating plasma into the chamber 210, wherein the gas introduced through the gas inlet 214 can be a compound gas represented by SiₓO_{y}C_{z}NₗHₘ, wherein x, y, z, l and m are 0 or integers, including SiH₄ gas, Si(OC₂H₅) gas, (CH₃)₂Si(OCH₃)₂ gas and C₆H₆ gas.

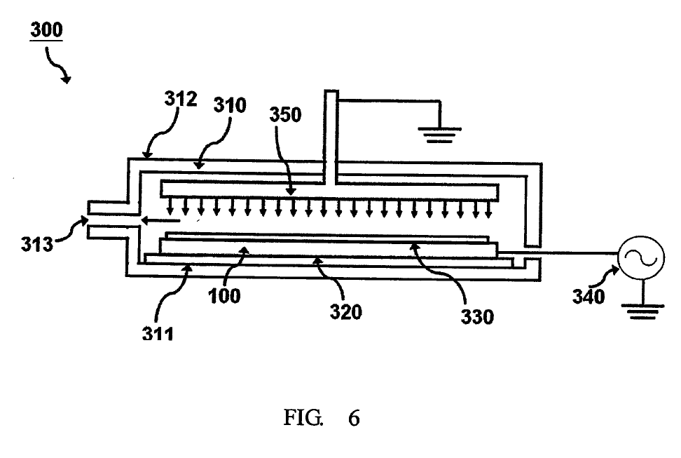

Now referring to FIG. 6, FIG. 6 is a schematic diagram illustrating an injection-typed capacitor-coupled plasma apparatus according to another embodiment of the present invention. The injection-typed capacitor-coupled plasma apparatus a chamber 310, a stage 320, a slotted electrode 100 having uniform electric field distribution, a gas outlet 350 and a gas inlet 313.

In the present embodiment, the chamber 310 has a first chamber surface 312 grounded and a second chamber surface 311, and is used for providing required processing space. The gas inlet 350 is disposed on the second chamber surface 312 for introducing gas required for generating plasma into the chamber 310, wherein the gas introduced through the gas inlet 350 can be a compound gas represented by SiₓO_{y}C_{z}NₗHₘ, wherein x, y, z, l and m are 0 or integers, including SiH₄ gas, Si(OC₂H₅) gas, (CH₃)₂Si(OCH₃)₂ gas and C₆H₆ gas. The stage 320 is disposed on the first chamber surface 311 for holding, the electrode required for performing a process in the chamber 310, wherein the stage 320 adopts isolation material to electrically isolate the first chamber surface 311 from the electrode required for performing the process, wherein the material forming the stage 320 can be selected from the group consisting of silicon, GaAs, ceramics, glass, fiberglass, hydrocarbon-ceramic composites, teflon, teflon-fiberglass composites and teflon-ceramic composites.

In the present embodiment, the slotted electrode 100 is disposed on the stage 320 for generating a uniform electric field in the chamber 310. A capacitor effect is formed between the slotted electrode 100 and the gas inlet 350 of the chamber 310, thereby forming plasma, and another capacitor effect is formed between the slotted electrode 100 and the first chamber surface 311, wherein the optimum length of the slotted electrode 100 is about 0.08 of the guided wavelength, and the optimum width of thereof is about 0.03 of the guided wavelength. When a process is performed, a processed substrate 330 is disposed above the slotted electrode 100 for performing plasma reaction, wherein the material forming the processed substrate 330 is selected from the group consisting of a suspension substrate, a silicon substrate, a GaAs substrate, a ceramic substrate, a glass substrate, a fiberglass substrate, a hydrocarbon-ceramic substrate, a teflon substrate, a teflon-fiberglass substrate and a teflon-ceramic substrate.

Besides, the gas outlet 313 is disposed on the second chamber surface 312 for exhausting the waste gas generated by the process in the chamber 210 and vacuuming the chamber 310.

It is known from the embodiments described above that the slotted electrode 100 of the present invention advantageously has a simplified structure; can be used for processing large-sized substrates; has highly commercialized value; and can be widely applied in plasma processing apparatuses.

While the present invention has been described by way of example and in terms of preferred embodiment, it is to be understood that the present invention is not limited thereto. To the contrary, it is intended to cover various modifications and similar arrangements. Therefore, the scope of the appended claims should be accorded the broadest interpretation to encompass all such modifications and similar arrangements.

What is claimed is:

1. A slotted electrode, comprising:
an electrode plate having a first surface, a second surface opposite to said first surface, a first side, a second side opposite to said first side, and a third side, wherein said electrode plate is electrically connected to a radio frequency (RF) current source for generating an electric field;
a perturbation slot segment adjacent to said first side, wherein said perturbation slot segment is symmetrically formed from said first surface to said second surface for controlling the intensity distribution of said electric field;
a first edge perturbation slot segment opposite to said perturbation slot segment, wherein said first edge perturbation slot segment is adjacent to said second side and is symmetrically formed from said first surface to said second surface, thereby controlling the intensity distribution of said electric field on one edge of said electrode plate; and
at least one second edge perturbation slot segment oriented orthogonal to said first edge perturbation slot segment, wherein said second edge perturbation slot segment is adjacent to said third side, and is symmetrically formed from said first surface to said second surface, thereby controlling the intensity distribution of said electric field on another at least one edge of said electrode plate;
wherein said perturbation slot segment is located at the same side with said RF current source.

2. The slotted electrode of claim 1, wherein said electrode plate is applicable to an atmospheric pressure chemical vapor deposition (APCVD) system, a low pressure chemical vapor deposition (LPCVD) system, a high density plasma chemical vapor deposition (HDPCVD) system, a plasma-enhanced chemical vapor deposition (PECVD) system and an inductively coupled plasma (ICP) etching system.

3. The slotted electrode of claim 1, wherein the material forming said electrode plate is selected from the group consisting of aluminum, aluminum-coated material, silicon, quartz, silicon carbide, silicon nitride, carbon, aluminum nitride, sapphire, polyidmide and teflon.

4. The slotted electrode of claim 1, wherein the shape of said electrode plate from the top view is selected from the group consisting of a rectangle, a circle, a hexagon and a polygon.

5. The slotted electrode of claim 1, wherein said RF current source is operated at a frequency ranged from 10 MHz to 10 GHz.

6. The slotted electrode of claim 1, wherein said RF current source is operated at a frequency of 13.56 MHz.

7. The slotted electrode of claim 1, wherein the size of the electrode plate is ranged from 0.0001 to 0.5 of the guided wavelength relative to the operation frequency of said RF current source.

8. The slotted electrode of claim 1, wherein the impedance of said RF current source fed to said electrode plate is ranged from 1 ohm to 300 ohm.

9. A capacitor-coupled plasma apparatus, comprising:
a chamber having a first chamber surface and a second chamber surface, wherein said chamber is grounded, and is used for providing required processing space;
a stage disposed on said first chamber surface;
a slotted electrode disposed on said stage for generating an electric field, said slotted electrode comprising:
an electrode plate having a first surface, a second surface opposite to said first surface, a first side, a second side opposite to said first side, and a third side, wherein said electrode plate is electrically connected to a radio frequency (RF) current source for generating an electric field;
a perturbation slot segment adjacent to said first side, wherein said perturbation slot segment is symmetrically formed from said first surface to said second surface for controlling the intensity distribution of said electric field;
a first edge perturbation slot segment opposite to said perturbation slot segment, wherein said first edge perturbation slot segment is adjacent to said second side and is symmetrically formed from said first surface to said second surface, thereby controlling the intensity distribution of said electric field on one edge of said electrode plate; and
at least one second edge perturbation slot segment oriented orthogonal to said first edge perturbation slot segment, wherein said second edge perturbation slot segment is adjacent to said third side, and is symmetrically formed from said first surface to said second surface, thereby controlling the intensity distribution of said electric field on another at least one edge of said electrode plate;
wherein said perturbation slot segment is located at the same side with said RF current source;
a gas outlet disposed on said second chamber surface for exhausting gas out of said chamber;
a gas inlet disposed on said second chamber surface for introducing gas into said chamber.

10. The capacitor-coupled plasma apparatus of claim 9, wherein a processed substrate is disposed above said slotted electrode.

11. The capacitor-coupled plasma apparatus of claim 10, wherein said processed substrate does not contact said perturbation slot segment, said first edge perturbation slot segment and said second edge perturbation slot segments.

12. The capacitor-coupled plasma apparatus of claim 9, wherein said capacitor-coupled plasma apparatus is an injection-typed capacitor-coupled plasma apparatus, wherein said gas inlet located at said second chamber surface opposite to said slotted electrode.

13. The capacitor-coupled plasma apparatus of claim 9, wherein the material forming said electrode plate is selected from the group consisting of aluminum, aluminum-coated material, silicon, quartz, silicon carbide, silicon nitride, carbon, aluminum nitride, sapphire, polyidmide and teflon.

14. The capacitor-coupled plasma apparatus of claim 9, wherein the shape of said electrode plate from the top view is selected from the group consisting of a rectangle, a circle, a hexagon and a polygon.

15. The capacitor-coupled plasma apparatus of claim 9, wherein said RF current source is operated at a frequency ranged from 10 MHz to 10 GHz.

16. The capacitor-coupled plasma apparatus of claim 9, wherein said RF current source is operated at a frequency of 13.56 MHz.

17. The capacitor-coupled plasma apparatus of claim 9, wherein the size of the electrode plate is ranged from 0.0001 to 0.5 of the guided wavelength relative to the operation frequency of said RF current source.

18. The capacitor-coupled plasma apparatus of claim 9, wherein the impedance of said RF current source fed to said electrode plate is ranged from 1 ohm to 300 ohm.

19. The capacitor-coupled plasma apparatus of claim 9, wherein the impedance of said RF current source is adjusted by using an impedance matching circuit.

20. The capacitor-coupled plasma apparatus of claim 9, wherein said chamber is a grounded metal chamber.
